(19) United States
(12) Patent Application Publication
(10) Pub. No.: US 2014/0060609 A1
(43) Pub. Date: Mar. 6, 2014

(54) MONOLITHIC MODULE ASSEMBLY FOR STANDARD CRYSTALLINE SILICON SOLAR CELLS

(71) Applicants: PRABHAT KUMAR, Fremont, CA (US); Sunhom Paak, Saratoga, CA (US); James M. Gee, Albuquerque, NM (US)

(72) Inventors: PRABHAT KUMAR, Fremont, CA (US); Sunhom Paak, Saratoga, CA (US); James M. Gee, Albuquerque, NM (US)

(73) Assignee: APPLIED MATERIALS, INC., Santa Clara, CA (US)

(21) Appl. No.: 13/647,152

(22) Filed: Oct. 8, 2012

Related U.S. Application Data
(60) Provisional application No. 61/551,618, filed on Oct. 26, 2011.

(51) Int. Cl. H01L 31/05; H01L 31/18

(52) U.S. Cl. CPC H01L 31/0504; H01L 31/18
USPC 136/244; 438/66

(57) ABSTRACT

Apparatuses and assembly methods are provided for a monolithic solar cell panel assembly. The assembly comprises an array of solar cells having front electrical contacts and back electrical contacts, wherein a first set of the solar cells in the array are aligned to be electrically connected in series through a back circuit sheet having an array of back metal contacts connected to corresponding back electrical contacts on the first set of solar cells, and through a front circuit sheet having an array of front metal contacts connected to corresponding front electrical contacts on the first set of solar cells. Electrical connections may be made in a lamination step, in which an encapsulant polymer flows into gaps and an interconnect material connects the circuits to form the monolithic solar cell panel assembly.

### CROSS-REFERENCE TO RELATED APPLICATION/PRIORITY CLAIM

This application claims the benefit of U.S. Provisional Application No. 61/551,618, filed on Oct. 26, 2011, which is herein incorporated by reference in its entirety.

### BACKGROUND OF THE INVENTION

1. Field of the Invention

Methods and apparatuses are provided that relate to module assembly of solar cells. Further embodiments relate to monolothic module assembly of conventional solar cells, in which electrical connections may be provided to electrical contacts on both front and rear surfaces of the solar cells during a lamination step.

2. Description of the Related Art

Crystalline-silicon photovoltaic solar cells can be electrically connected into a solar cell circuit to produce acceptable voltages. The solar cell circuit may also provide other functions like bypass diodes to limit internal heating when a solar cell in the circuit is shaded. A photovoltaic (PV) module may enclose the solar cell circuit in a package for environmental protection. For example, the photovoltaic module can encapsulate the solar cell circuit with a glass cover, polymer and a backsheet. One layer structure may comprise: glass/polymer/solar cell/polymer/backsheet. The encapsulation is typically performed in a lamination step that applies pressure and temperature on the layer structure while under vacuum. The photovoltaic module frequently includes a frame around the encapsulated cell assembly for ease of handling, mechanical strength, and to provide locations to mount the photovoltaic module. The photovoltaic module typically includes a “junction box” where electrical connection to other components of the complete photovoltaic system (“cables”) is made.

A typical fabrication sequence for photovoltaic modules may comprise: assembling the solar cell circuit, assembling the layered structure (glass, polymer, solar cell circuit, polymer, backsheet), and laminating the layered structure. The final steps may comprise installing the module frame and junction box, and testing the module. The solar cell circuit is typically made with automated tools (such as “stringer/tabbers”) that connect the solar cells in electrical series with copper (Cu) flat ribbon wires (or other interconnects.) Herein, the term “conventional” solar cell” is used to describe a solar cell that has electrical contacts on both the front surface and the rear surface. Most solar cells are of this nature. Crystalline silicon solar cells may be manufactured in this configuration. Conventional solar cells typically have a Cu interconnect to weave from the front surface to the rear surface of the adjacent solar cell. Several strings of series-connected solar cells may then be electrically connected with wide Cu ribbons (“busses”) to complete the circuit. These busses may also bring the current to the junction box from several points in the circuit for the bypass diodes and for connection to the cables. This photovoltaic module design and assembly approach is well known in the industry.

However, significant limitations exist for assembling modules using conventional solar cells. First, the process of electrically connecting solar cells in series is difficult to automate so that stringer/tabbers have limited throughput and are expensive. Further, the assembled solar cell circuit is very fragile prior to the lamination step. In addition, the Cu ribbon interconnect is stressed. As a result, the conductivity of the Cu interconnect is limited and the electrical losses due to the interconnect are large. Moreover, issues with fragility and the Cu ribbon interconnect make the assembly process difficult with thin crystalline-silicon solar cells, even though using thinner silicon (Si) is desirable to reduce the cost of the solar cell. Additionally, the spacing between solar cells must be large enough to accommodate the stress relief for the Cu interconnect wire, which reduces the module efficiency due to the non-utilized space between solar cells. This is particularly true when using silicon solar cells with positive and negative polarity contacts on opposite surfaces. Accordingly, the assembly process has many steps that increase the manufacturing cost, and improvements are greatly desired.

In order to simplify the electrical interconnection of the solar cells, some PV modules are assembled using back-contact solar cells, in which both the negative- and positive-polarity contacts are located on the back surface of each solar cell. Module assembly for back-contact solar cells is described by U.S. Pat. Nos. 5,951,786 and 5,972,732 to James M. Gee, et al. However, this approach abandons the configuration of conventional solar cells. And back-contact solar cells may require additional expense and/or thickness than can be obtained with conventional solar cells, such as by providing the opposite polarity electrical connections on opposite sides of the solar cell.

Therefore, a need exists for improved methods and apparatuses for module assembly of solar cells.

### SUMMARY OF THE INVENTION

Apparatuses and methods for modular assembly of solar cells are provided. In one embodiment, a solar cell assembly is provided with conventional solar cells connected by front and back metal circuit planes in a module assembly. In another embodiment, a process is provided for monolithic module assembly that starts with a backsheet with a patterned electrical conductor layer. Production of such patterned conductor layers on flexible large-area substrates may be according to techniques from the printed-circuit board and flexible-circuit industries. Solar cells having front and back contacts may be placed on this flexible circuit backsheet with a pick-and-place tool to provide very accurate positioning with high throughput. A second patterned electrical conductor layer can be placed on the front side of the solar cells. This second patterned electrical conductor layer may be provided as part of a front-sheet. The solar cells can make electrical connection to the patterned electrical conductors on the front and back sides during a lamination step, thereby making the laminated package and electrical circuit in a single step and with simple automation.

The backsheet and/or the front-sheet may comprise materials like solders or conductive adhesives that form the electrical connection during the lamination temperature-pressure cycle. The backsheet and/or the front-sheet could optionally include an electrical insulator layer to prevent shorting of the electrical conductors on the backsheet the front-sheet with the conductors on the solar cell. A polymer layer can also be provided between the backsheet or the front-sheet and the solar cell for the encapsulation. These additional layers could be applied during the assembly, or some could be provided integrated with a flexible-circuit backsheet or front-sheet. The polymer layer could provide low-stress adhesion of the backsheet or the front-sheet to the solar cell. The polymer encapsulation layer could either be integrated with the backsheet or the front-sheet, or could be inserted between the backsheet or the front-sheet and the cells during the assembly process. Other alternatives may be used as well. For example, metal granules can be deposited on glass, which can punch through EVA or PVF during lamination. In another example, metal lines can be deposited on PVF or other polymer substrate using roll-to-roll deposition.

In one embodiment, an apparatus for generating photovoltaic power is provided, comprising an array of solar cells having front electrical contacts and back electrical contacts, wherein a first set of the solar cells in the array are positioned to be electrically connected in series; a back circuit sheet comprising an array of back metal contacts, wherein a first set of the back metal contacts are positioned to electrically connect to corresponding back electrical contacts on the first set of solar cells; and a front circuit sheet comprising an array of front metal contacts, wherein a first set of the front metal contacts are positioned to electrically connect to corresponding front electrical contacts on the first set of solar cells.

In another embodiment, one or more of the back metal contacts in the back circuit sheet are positioned to electrically connect to one or more of the front metal contacts in the front circuit sheet in an area defined by one or more gaps between adjacent solar cells in the first set of solar cells. In a further embodiment, one or more back-side interconnect materials that establish a plurality of electrical connections between the back circuit sheet and the back electrical contacts in the array of solar cells; and one or more front-side interconnect materials that establish a plurality of electrical connections between the front circuit sheet and the front electrical contacts in the array of solar cells.

In yet another embodiment there is less interconnect material on the front-side than on the back-side. A further embodiment provides that the front metal contacts are thinner than the back metal contacts. In addition, the front metal contacts may comprise thin lines of copper, and the back metal contacts comprise aluminum and copper.

Further, the front metal contacts comprise front metal bus bars, and the back metal contacts comprise back metal bus bars, the front metal bus bars on the first set of solar cells extend horizontally past a proximate edge of each of the solar cells, and the back metal bus bars on the first set of solar cells extend horizontally past a distal edge of each of the solar cells. In another embodiment, an interconnect material electrically connects the front metal bus bars to the back metal bus bars so as to connect the first set of solar cells in series. A further embodiment provides for a transparent polymer layer positioned over the front circuit sheet; and a transparent front layer positioned over the transparent polymer layer. In addition, one or more layers of an encapsulant polymer may be provided, wherein the electrical connections are formed during a lamination step.

In another embodiment, a module assembly of solar cells is provided comprising: a backsheet; a back circuit positioned over the back sheet and having a set of back metal contacts; an array of solar cells positioned over the back metal circuit plane, wherein each of the solar cells has front electrical contacts of negative polarity and back electrical contacts of positive polarity; and a front circuit positioned over the array of solar cells and having a set of front metal contacts, wherein at least a first set of the solar cells are positioned to be electrically connected in series by the back and front circuits.

In a further embodiment, for the first set of solar cells, each back electrical contact of a solar cell is electrically connected to a corresponding back metal contact on the back circuit, and each front electrical contact of a solar cell is electrically connected to a corresponding front metal contact on the front circuit, and wherein at least one front metal contact, connected to a first solar cell, is electrically connected to at least one back metal contact connected to a second solar cell positioned adjacent to the first solar cell.

Further embodiments provide a first pattern of one or more interconnect materials providing electrical connections between the back circuit and the back electrical contacts of the array of solar cells; and a second pattern of one or more interconnect materials providing electrical connections between the front circuit and the front electrical contacts of the array of solar cells. Additionally, the first pattern of depositions of one or more interconnect materials may further provide electrical connections between the front circuit and the back circuit, and the electrical connections between the front circuit and the back circuit may be formed in at least a plurality of gaps between adjacent solar cells in the first set of solar cells that are connected in series.

Other embodiments provide a method for monolithic manufacturing assembly of a solar cell panel, comprising the steps of: obtaining a set of solar cells having similar electrical properties that may be used together to manufacture a solar cell panel; laying down a backsheet; providing a back metal circuit sheet over the backsheet; positioning an array of solar cells over a pattern of interconnect material, wherein each solar cell has one or more front electrical contacts and one or more back electrical contacts; providing a front metal circuit sheet over the interconnect material; and laying down a front cover over the front metal circuit sheet. (It should be noted that the backsheet may comprise the back metal circuit.)

The method may further comprise providing a back pattern of interconnect material over the back metal circuit sheet; providing a back encapsulant over the interconnect material and the back metal circuit sheet, before positioning the array of solar cells; providing a front encapsulant over the array of solar cells; and providing a front pattern of interconnect material over the front encapsulant, before providing the front metal circuit sheet.

In addition, the method may further comprise: providing a back polymer layer over the backsheet before providing the back metal circuit sheet; and providing a front polymer layer over the front metal circuit sheet before laying down the front cover. Further, the method may comprise providing electrical connections during a lamination step. Other embodiments provide that less interconnect material is used on the back pattern than on the front pattern, and/or the front metal circuit sheet comprises thinner metal contacts than the back metal circuit sheet. Moreover, the back metal circuit sheet may further comprises back metal bus bars and a pattern of interconnect material over portions of the back metal bus bars, positioned to make electrical connection to the back electrical contacts of the solar cells and the front circuit sheet.

### BRIEF DESCRIPTION OF THE DRAWINGS

Advantages of the features cited above may become apparent to those skilled in the art by reference to illustrative embodiments, some of which are shown in the following drawings. The drawings are not intended to be to scale, and embodiments shown are not to be considered limiting in scope.

FIG. 1 illustrates a schematic diagram of an expanded module assembly for conventional solar cells.

FIG. 2 illustrates a flow chart of methods relating to module assembly.

FIG. 3 illustrates a cross section view of an example module assembly.

FIG. 4 illustrates schematically an array of solar cells, such as may be used in module assembly.

FIG. 5 illustrates schematically a front metal circuit plane.

FIG. 6 illustrates schematically a rear metal circuit plane.

FIG. 7 illustrates schematically a combined solar module assembly of an array of solar cells positioned between front and rear metal circuit sheets.

FIG. 8 illustrates a cross section view of an example module assembly according to another embodiment.

It is contemplated that elements and features of one embodiment may be beneficially incorporated in other embodiments without further recitation.

### DETAILED DESCRIPTION

Embodiments discussed herein provide assemblies of solar modules and methods for producing assemblies of solar modules. Further, embodiments are described for approaches to implement module assembly with conventional silicon solar cells.

Conventional silicon solar cells have contacts on both the front and back surfaces, so an electrical connection must be provided to both surfaces of the solar cell. For example, standard crystalline solar cells may be made in the conventional configuration, with positive and negative polarity contacts provided on opposite surfaces of the solar cell. To assemble a module of solar cells, the solar cells may be electrically connected in series. The electrical connection may be provided during assembly by placing electrically conductive elements in contact with one another. Then, the assembly may be heated to bind the electrically conductive elements. Heat may be provided in a lamination step. Thus, the solar module may be assembled in a monolithic assembly process. “Monolithic module assembly” refers to assembly of the solar cell electrical circuit during a lamination step. This approach also opens the possibility of new assembly approaches, new module designs and new circuit configurations.

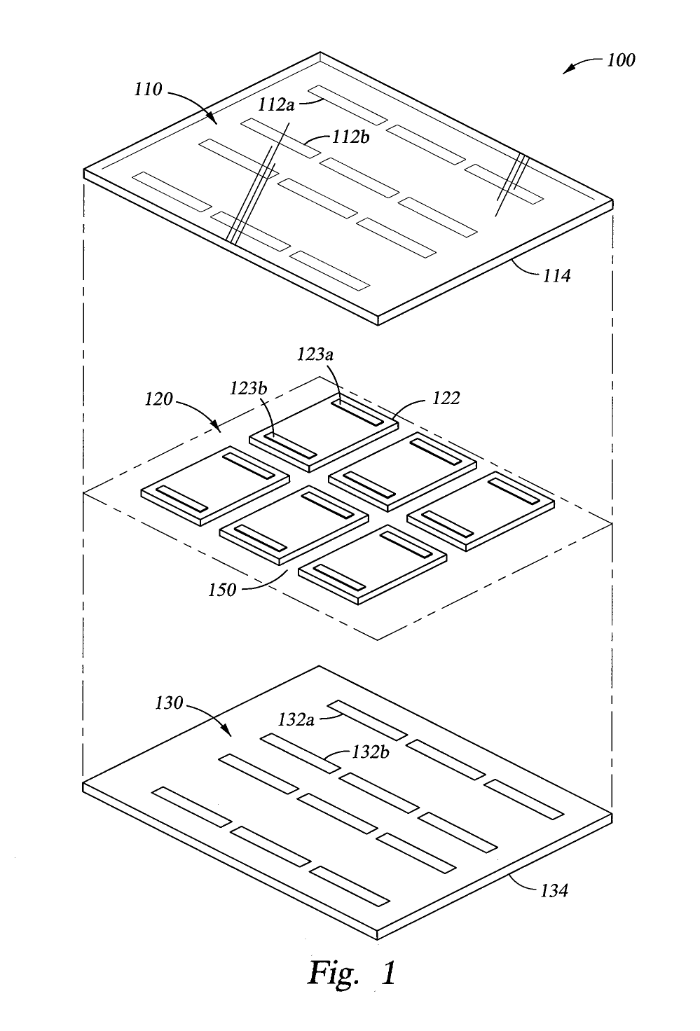

Some embodiments provide for manufacturing panels of conventional solar cells using front and back metal circuit planes. Further embodiments provide for monolithic assembly of these solar cell panels. A schematic diagram of one such assembly is shown in FIG. 1. This assembly consists of front and back metal circuitry planes and solar cells in between the metal planes. This assembly is especially valuable as it allows for producing solar cell modules from thin wafers provided by conventional solar cell configurations. A front plane may be provided with metal circuitry for connecting to the front contacts on the solar cells. A back plane may be provided with metal circuitry for connecting to the back contacts on the solar cells. Further, the front circuit plane and the back circuit plane may be positioned so that the front and back circuits can connect at certain points, such as between the solar cells. Accordingly, a first circuit plane may be provided for connecting to negative polarity solar cell contacts on a top side of an array of solar cells, and a second circuit plane may be provided to connect to positive polarity solar cell contacts on a bottom side of the array of solar cells. The first and second circuit planes may be positioned to connect at gaps between adjacent solar cells. Further, a monolithic assembly method may be used to assemble a module of solar cells by connecting the solar cell electrical circuit in a lamination step or a heating step.

FIG. 1 illustrates an expanded module assembly 100 for conventional solar cells 122. The solar cells 122 are positioned in a horizontal array 120. In this example, the array has two rows of three solar cells each. A gap 150 is positioned between adjacent solar cells in each row. The three solar cells in each row may be electrically connected in series by electrical connections to the front and back circuit planes (110 and 130, respectively). Adjacent rows may also be connected. Modules may of course be made larger. For example, a six by ten array of solar cells may be assembled into a module having sixty solar cells with a combined surface area of 1.65 square meters. An array having seventy two cells, or other desired number, may also be assembled into a module.

The solar cells 122 are conventional solar cells, with front electrical contacts 123a and 123b provided on the front surface. In this embodiment, there are two front electrical contacts provided, which have the same polarity, typically negative polarity. In this embodiment, the front electrical contacts 123a and 123b are metal contacts. More or less contacts may be provided for various embodiments. Further, the front electrical contacts 123a and 123b are shown as linear strips. Other configurations may be used, as desired. Back electrical contacts (not shown) are provided on a back surface of the solar cells. The back electrical contacts have the opposite polarity to the front electrical contacts.

The front metal plane 110 is positioned over the array 120 of solar cells 122. The front metal plane 110 has an array 114 of pairs of electrically conductive elements 112a and 112b, positioned to contact the front electrical contacts 123a and 123b of corresponding solar cells. Electrically conductive elements 112a and 112b may extend horizontally beyond an edge of the solar cell 122 into the gap 150, for the purpose of electrically connecting to an adjacent solar cell. The front metal plane 110 may further comprise a transparent material (not shown) that allows light to pass through to the solar cells 122. The electrically conductive elements 112 may be pre-patterned on this transparent material. For example, electrically conductive adhesive (referred to herein as “ECA”) may be placed on a layer of glass. Transparent plastics, polymers or composite compounds may also be used, such as polyvinyl fluoride, or combinations of glass and plastics. The transparent material may be selected for long life in both harsh outdoor weather and sunshine.

The back metal plane 130 is positioned under the array 120 of solar cells 122. The back metal plane 130 has an array 134 of pairs of back electrically conductive elements 132a and 132b, positioned to contact the back electrical contacts (not shown) of corresponding solar cells. The back electrical contacts may match the layout of the front electrical contacts, which in this case are two linear electrical contacts spread out across the solar cell. In some embodiments, the back electrical contacts may be in a different configuration than the front electrical contacts. For example, a series of three “joints” or contact sections may be provided opposite each linear front contact. It should be appreciated that the monolithic module assembly discussed herein permits various configurations of electrical contacts to be used.

Electrically conductive elements 132a and 132b may extend horizontally beyond an edge of the solar cell 122 into a gap (such as gap 150) between the solar cells, for the purpose of electrically connecting to an adjacent solar cell. In one embodiment, the back electrically conductive elements connect to the front electrically conductive elements of an adjacent solar cell. Connections between the front and back electrically conductive elements may take place in gaps between adjacent solar cells, or in spaces on the sides of solar cells. In some embodiments, openings may even be provided within solar cells for connections between the front and back electrically conductive elements. The back metal plane 130 may further comprise a backsheet (not shown) onto which the back electrically conductive elements 132 are positioned. In some embodiments, the backsheet may comprise the material Tedlar®, which is commercially available from DuPont.

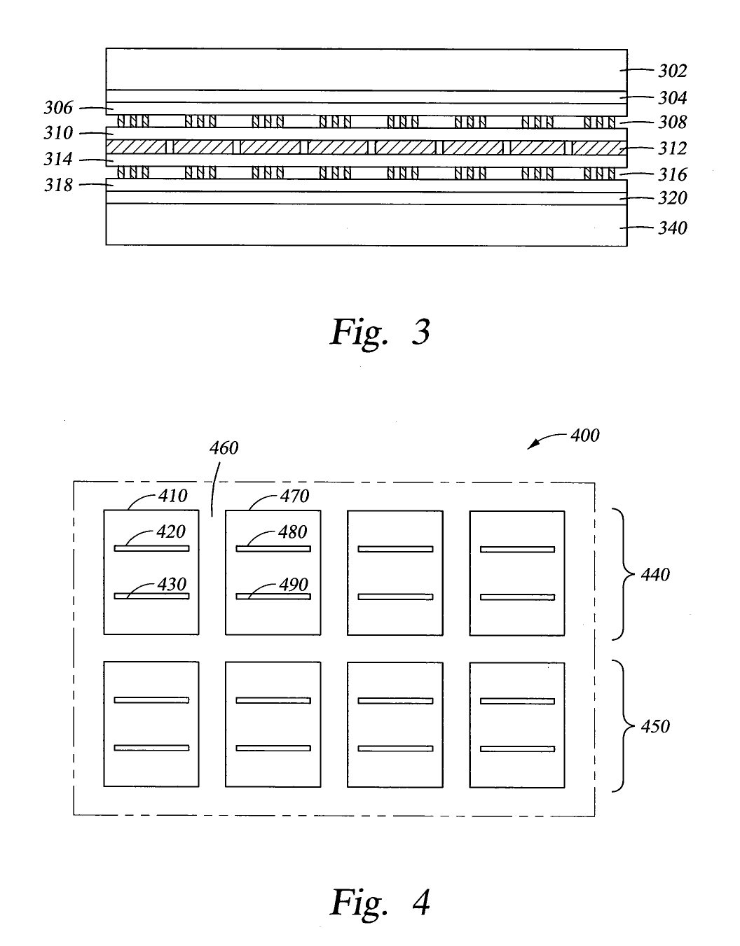

FIG. 3 illustrates a cross sectional view of an example solar cell module assembly 300. Going in order from top to bottom, a top or front layer 302 comprises a transparent material such as glass, polymer, or combinations of the same. Materials used on the front side of the solar cell module assembly may be selected for optical properties, such as transparency, so that solar radiation may be transmitted through the material, or for resistivity to discoloration. For example, a material may be selected that is transparent to light in the spectrum ranges of near-ultraviolet, visible, and near-infrared. Alternatively, a material may be selected for transmitting wider ranges of the electromagnetic spectrum, such as extending into the ultraviolet and/or infrared regions. The material may also be selected for properties such as physical strength, flexibility, durability, abrasion resistance and/or ease of cleaning; chemical resistivity, such as being resistant to staining or discoloration when exposed to various substances like oils, acids or bases; electrical insulation; or the ability to bond or adhere to other layers or components in the assembly. Surface appearance may also be taken into consideration. For example, in some embodiments materials are selected to avoid high reflectivity of light. Alternatively or in addition, the top layer 302 may be provided with thin films on its surface that provide various advantages, such as minimizing the amount of light reflected to the surrounding environment, or to facilitate other resistances or properties. These properties may also be selected for consistent performance over a range of temperatures and weather conditions. In some embodiments, glass may be used for the top layer 302. The glass may further comprise thin films on its front and/or back surfaces. In other embodiments, the top layer may comprise a transparent polyvinyl fluoride (PVF) compound. In further embodiments, a polyvinyl fluoride film such as Tedlar® may be used. Additionally, the top layer 302 may comprise a combination of layers that together form the top layer 302.

Next, a front intermediate layer 304 is provided, which may comprise an encapsulant material or a sheet of encapsulant material, such as ethylene vinyl acetate (referred to herein as “EVA”). Alternatively, a material such as Tedlar® may be used.

The next layer of the assembly may be a front metal layer 306. Alternatively, other electrically conductive material may be used in this layer. The front metal layer 306 may comprise a sheet having electrically conductive elements (not shown) positioned in a desired pattern for electrically connecting solar cells.

Below the front metal layer 306, a front interconnect material 308 is positioned. The front interconnect material 308 may be disposed in a pattern to provide electrical connections between the front metal layer 306 and electrical contacts for solar cells. (The embodiment illustrated in FIG. 3 shows three deposits of interconnect material disposed above each solar cell 312, which gaps in between each deposit in a section of deposits, and gaps between adjacent sections of deposits. However, it should be appreciated that this is for illustration, and other configurations may be utilized.) Next, a front encapsulant layer 310 may be positioned underneath the front interconnect material 308. The front encapsulant layer 310 may comprise a material such as EVA or Tedlar®. During lamination, the encapsulant material may flow into gaps provided in the assembly, such as the gaps shown between the front interconnect material 308 or between the solar cells 312.

Next, an array of solar cells 312 is provided. Adjacent solar cells in a row may be separated by a gap. The solar cells have electrical contacts (not shown) on both the top and bottom surfaces. The electrical contacts may be positioned so that the solar cells 312 in a row can be electrically connected, during a lamination step, by use of the front interconnect material 308 and the front metal layer 306. For example, metal granules may be deposited on glass that can punch through EVA or Tedlar® during lamination and establish electrical connections between the solar cells 312 and the front metal layer 306. Additionally, or in the alternative, metal lines can be deposited. In one embodiment, metal lines may be deposited on a polymer substrate. In a further embodiment, metal lines are deposited using roll-to-roll deposition. It should be appreciated that layers on the front surface of the solar cell may be selected for transparency. Further embodiments minimize the amount of surface area on the front side of the solar cell that is used by metal electrical contacts, which do not transmit light. For example, materials with high electrical conductivity may be used on the front side of the solar cell so that electrical connections are made with minimal amounts of material.

Under the layer of solar cells 312, a back encapsulant layer 314 may be provided. The back encapsulant layer 314 may be EVA or Tedlar®. The back encapsulant layer 314 may be the same material as the front encapsulant layer 310. Alternatively, a different material may be used on the bottom because materials under the solar cells 312 may not have to be transparent or may not need to minimize the amount of light blocking components.

Next, a back interconnect material 316 may be provided. Similar to the discussion above, this material can be used to provide electrical connections to back electrical contacts (not shown) on the solar cells 312. Thus, the back interconnect material 316 may be disposed in a pattern to provide electrical connections between a back metal layer 318 and back electrical contacts (not shown) for solar cells 312. During lamination, the encapsulant material in back encapsulant layer 314 may flow into gaps provided in the assembly, such as the gaps shown between the back interconnect material 316 or the gaps shown between the solar cells 312.

Beneath the back interconnect material 316, a back metal layer 318 is provided. Alternatively, other electrically conductive material may be used in this layer. The back metal layer 318 may be a sheet having electrically conductive elements (not shown) positioned in a desired pattern for electrically connecting solar cells. Electrical connections may be made during a lamination step, as discussed above.

Next, a back intermediate layer 320 may be provided, comprising an encapsulant material or a sheet of encapsulant material, such as EVA or Tedlar®. The back intermediate layer 320 may overlay a backsheet 340. Backsheet 340 may be a substrate. In a further embodiment, the backsheet 340 comprises a PVF polymer. This layer may also provide support for the assembly.

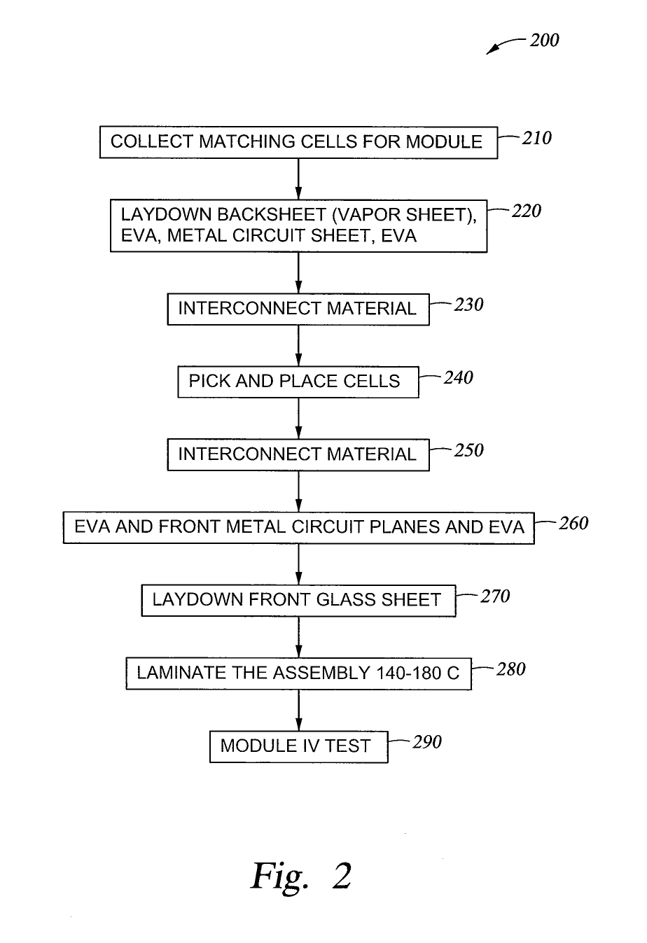

FIG. 2 provides an example flow chart 200 relating to monolithic module assembly for conventional solar cells in the novel configuration described herein, according to some embodiments. (It is to be understood that an illustrated step in the flow chart may further comprise additional steps, in accordance with additional embodiments.) In the process step “matching cells for module” 210, solar cells are identified and collected that are suitable for use together in a panel. A sorter may be used to collect matching solar cells according to similar properties, such as power production, peak power production or conversion efficiency. Power measurements may be taken for properties such as Pmax, Imax or Vmax and other metrics that are known in the art. The sorting step may also group solar cells according to one or more ranges of certain measurements. For example, a sorter (not shown) may categorize solar cells that have different ranges of efficiencies, so that solar cells are collected into a group with a similar range of efficiency. In one embodiment, the sorter may form different groups of solar cells having efficiency ratings of 18.0-18.2%, 18.2-18.4 and 18.4-18.6%, respectively. (Other ranges or additional ranges are used as well.) A module may then be assembled using solar cells from one of these groups, having similar efficiency ratings.

In the process step “Laydown backsheet (vapor sheet), EVA, metal circuit sheet, EVA” 220, a backsheet is laid down. The backsheet may have other layers on top of it. For example, a vapor sheet may be provided as well. In one embodiment, a backsheet may be provided with a first encapsulant layer on top of the backsheet, a metal circuit sheet on top of the first encapsulant layer, and a second encapsulant layer on top of the metal circuit sheet. The encapsulant may be EVA. In another embodiment, the backsheet is pre-made with various layers such that an electrically conductive circuit is provided on the backsheet. In a further embodiment, step 220 comprises multiple steps to provide one or more of these layers separately. In a further embodiment, a metal circuit sheet is laid down, in which electrically conductive contacts are pre-positioned on a sheet of material. In yet another embodiment, metal contacts are laid down to comprise a metal circuit layer. In one embodiment, a metal circuit sheet may be assembled on top of the backsheet (and/or any intermediate layers). A metal circuit sheet may also be provided that is made from a deposition and etching process. In one embodiment, metal lines are deposited on PVF or other polymer substrate, such as by using a roll-to-roll deposition. One example metal circuit sheet is shown in FIG. 6, which is discussed further below.

The metal contacts for the front or back circuits may comprise copper, or other electrically conductive metals or metallic compounds. The metal may be provided with a coating to improve bondability. Various substances may be used in the metal contacts such as tin, or organic solder preservative (OSP), or aluminum. Alternatively, copper clad aluminum may be used. In a further embodiment, the metal contacts comprise aluminum that is coated or plated with a bondable metal, such as copper. The thickness of the metal circuit sheet may depend on the selection of material. For example, a metal circuit sheet made using copper may be very thin, such as between 7-25 microns thick. In other embodiments, a metal circuit sheet may be between 25-35 microns thick. Alternatively, a metal circuit sheet using aluminum with copper on the aluminum may be 100-125 microns thick. (Metal contacts may be 2-3 mm wide, in some embodiments.)

The back metal circuit may be manufactured differently from the front metal circuit due to differences in design considerations. For example, a front metal circuit sheet needs to maximize light transmission to the solar cells. This affects the design considerations. Thus, the front metal circuit sheet may be made thinner than the back metal circuit sheet. And metal contacts on the front side may be made with less material, so as to be thinner or smaller. Further, the back metal circuit sheet does not need to be transparent. Thus, the back metal circuit sheet can be made thicker, it can provide structural support, and its metal contacts may be made wider or larger. Cost may also be an important consideration in material selection. Aluminum may be used to support copper connections on the back side, since a thicker layer of aluminum can be used without negatively impacting light transmission, as it might on the front sheet. In contrast, copper may be used on the front side without an aluminum support. In further embodiments, copper contacts on the front side may be made with less material (i.e., thinner) than metal contacts on the back side of the solar module assembly. Thus, according to some embodiments, the front metal circuit sheet may use more copper than the back metal circuit sheet, and the back metal circuit sheet may use aluminum and copper.

In process step “Interconnect material” 230, back-side interconnect material is positioned on the assembly. The interconnect material is positioned over metal contacts in the back metal circuit sheet. Further, the interconnect material is provided in a pattern configured for electrical connection of the back circuit to the back electrical contacts on the solar cells and/or for electrical connection of the back circuit to the front circuit. Polymer material such as EVA provided in step 220 may temporarily separate the interconnect material from the back metal circuit. In other embodiments, encapsulant is provided in the interconnect step 230, whether above or below or between deposits of interconnect material. In another example, encapsulant is provided over the interconnect material before the solar cells are positioned in the assembly. The interconnect material may electrically connect to the back metal circuit and to the solar cells during a lamination step 280, in which sufficient heat is provided for the interconnect material to pass through the polymer used and to connect or bond to the back metal circuit. (In an alternate embodiment, polymer is not used to separate the interconnect material from the metal circuit. A heating step may also be used to provide further bonding.)

The interconnect material (for the back-side or the front-side) may comprise electrically conductive adhesive (ECA). ECA may be epoxy resin based, or low temperature solder material, or solder paste. Metal granules can be deposited that can punch through EVA or PVF during lamination or heating to establish electrical connections. In one embodiment, metal is deposited on PVF or other polymers during a deposition process. In a further embodiment, a roll-to-roll deposition process is utilized. In another embodiment, a laser soldering step (not shown) is used to illuminate and heat a solder material to facilitate bonding. The laser soldering step may be provided after the lamination step 280. In a one embodiment, an ECA is selected to bond to metal contacts during lamination in a low temperature process. Interconnect thickness in a finished assembly may be determined by the encapsulant that surrounds it.

In process step “Pick and place cells” 240, solar cells are positioned onto the assembly. A pick-and-place tool may be used to provide accurate positioning with high throughput. The solar cells may be positioned into an array so that the back electrical contacts on the solar cells are positioned over interconnect material and/or portions of the back electrical circuit provided on the back metal circuit sheet. The array of solar cells may be positioned to form a completed circuit during the lamination step 280. Spaces may be created between adjacent solar cells to allow for thermal expansion. Additionally, gaps may be created between adjacent solar cells, which will be connected in series, to provide regions for circuit connections between the front and back circuit sheets.

In process step “Interconnect material” 250, interconnect material may be provided to the front-side of the solar cell assembly. An encapsulant material, such as EVA, may be provided beneath the interconnect material, and/or above it. Further, the interconnect material may be provided in a pattern configured for electrical connection of the front electrical contacts on the solar cells to the front circuit and/or for electrical connection of the front circuit to the back circuit. Polymer material such as EVA may temporarily separate the interconnect material from the solar cells and/or the front metal circuit. In other embodiments, encapsulant may be provided above or below or between deposits of interconnect material. In another example, encapsulant may be provided over the interconnect material before the solar cells are positioned in the assembly. The interconnect material may electrically connect to the front metal circuit and to the solar cells during the lamination step 280, in which sufficient heat energy is provided for the interconnect material to pass through the polymer used and to connect or bond to the back metal circuit. (In an alternate embodiment, polymer is not used to separate the interconnect material from the metal circuit. A heating step may also be used to provide further bonding.)

In process step “EVA and front metal circuit planes and EVA” 260, a front metal circuit is provided on the assembly. A front metal circuit plane may include more than one layer, and the front metal circuit plane may be provided in one step or assembled in more than one step. In one embodiment, in process step 250, a first front encapsulant may be placed on top of the array of solar cells, and interconnect material may be placed on top of the encapsulant. Then, in process step 260, a second front encapsulant layer may be provided over the interconnect material, and a front metal circuit sheet may be placed over the encapsulant layer. The interconnect material can form connections between the front circuit and the front electrical contacts on the solar cells during a lamination step or a heating step. In other embodiments, either the first or second encapsulant layer may not be used. In still other embodiments, the second front encapsulant layer may be positioned over the metal circuit sheet instead. In a further embodiment, a third front encapsulant layer may be placed on top of the front metal circuit sheet. The encapsulant may be EVA. (Interconnect material may also be provided in process step 260, in addition or instead of process step 250. In another alternative, interconnect material may be pre-positioned on the front metal circuit plane before the front metal circuit is positioned on the assembly.)

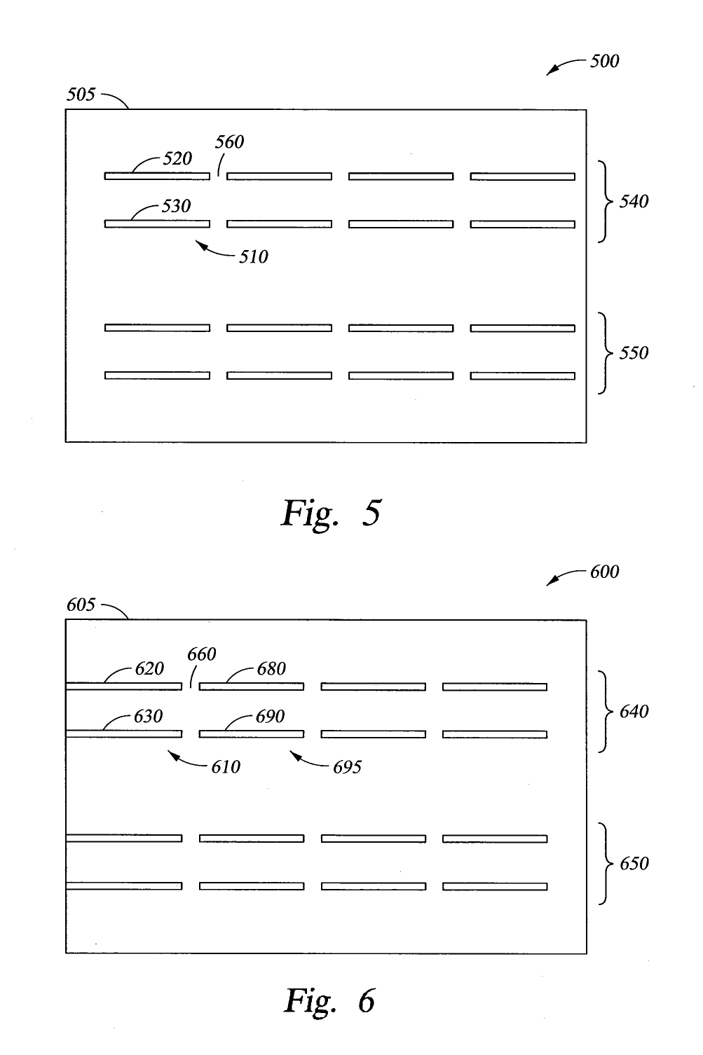

In one embodiment, the front metal circuit plane is pre-made with various layers such that an electrically conductive circuit is provided that is suitable for completing an electrical circuit when connected to the array of solar cells and the back metal circuit. In a further embodiment, process step 260 comprises multiple steps to provide one or more of these layers separately. In another embodiment, a metal circuit sheet is laid down, in which electrically conductive contacts are pre-positioned on a sheet of material. In yet another embodiment, metal contacts may be laid down to comprise a metal circuit layer. In a further embodiment, a metal circuit sheet may be assembled on top of a previous layer, such as the solar cell array, an encapsulant such as EVA, or an insulator. A metal circuit sheet may also be provided that is made from a deposition and etching process. In one embodiment, metal lines can be deposited on PVF or other polymer substrate, such as by using a roll-to-roll deposition. One example metal circuit sheet is shown in FIG. 5, which is discussed further below.

A front metal circuit plane may be manufactured using similar techniques to those discussed above for the back metal circuit. As discussed above, a front metal circuit plane may be manufactured differently from a back metal circuit plane to provide for greater transmission of light. Accordingly, materials used on the front side of the assembly may be selected to be thinner or more transparent than the back side. In one embodiment, a front metal circuit sheet is made from deposition and etching to provide micro-circuitry. In some embodiments, the front side of the assembly uses the same type of interconnect material as the back side. In other embodiments, less interconnect material is provided on the front side of the assembly. For example, back side interconnect material may be deposited to be around 200 microns thick or wide. In contrast, front-side interconnect material may be provided (or deposited) to be thinner than back-side interconnect material. For example, front side interconnect material may be between 25-50 microns thick or wide, or between 10-100 microns thick or wide. In a further embodiment, a different interconnect material is used on the front side than the back side, which may be selected so that the interconnect material is thinner on the front side than on the back.

In process step “Laydown front glass sheet” 270, a transparent front sheet is positioned on the assembly. The front sheet may comprise glass, or other suitable transparent cover material or polymers. In another embodiment, a front intermediate layer may be positioned on the assembly, over the metal circuit plane, which may improve bonding or adhesion to the front sheet. In one embodiment, process step 260 may include use of additional encapsulant, such as EVA or Tedlar®.

In process step “Laminate the assembly 140-180° C.” 280, a lamination step is conducted on the solar cell module assembly. Heat and/or pressure may be provided over a set amount of time to cause flow of encapsulant materials into gaps in the assembly, such as gaps between adjacent solar cells, gaps between interconnect material, or gaps between layers in the assembly. The lamination step may be run at a temperature of around 140-180° C. In one embodiment, a time-temperature tune profile may provide a recipe to heat the assembly slowly for around 15-20 minutes to a peak temperature of around 150° C.

During the lamination step, the solar cells can make electrical connection through the interconnect material to the front and back metal circuits, and the front and back metal circuits can make connection in gaps between the solar cells, thereby unifying the laminated package and electrical circuit in a single step and completing the assembly. Interconnect material may also be provided to connect the front and back metal circuits. In process step “Module IV test” 290, module IV (current—voltage) testing is conducted on the completed solar cell assembly.

Monolithic module assembly of a conventional solar cell with contacts on both side provides important advantages. First, single-step assembly reduces the number of steps and reduces manufacturing cost (since special cells do not have to be manufactured, and high manufacturing volume low cost solar cells can be used). Second, the planar geometry may be automated to reduce the cost and to improve the throughput of the production tools. Third, a smaller spacing between solar cells may be used when compared to conventional photovoltaic modules with Cu ribbon interconnects. Decreased spacing increases the module efficiency and reduces the cost. The Cu busses at the end of the modules can also be reduced or eliminated, which also reduces module size for reduced cost and improved efficiency. Fourth, the number and location of the contact points can be optimized since the geometry is only limited by the patterning technology. This is unlike stringer/tabbers where additional Cu interconnect straps or contacting points increase the cost of the assembly. The net result is that the cell and interconnect geometry can be optimized with monolithic module assembly using conventional solar cells with electrical connection laminations on both sides.

Fifth, the geometry is much more planar than previous assemblies, and thus will introduce less stress. Therefore, thin Si solar cells can be more easily used. Sixth, the electrical circuit on the backsheet can cover nearly the entire surface. The conductance of the electrical interconnects can be made higher because the effective cross sectional area of the back interconnects can be greater than the conductor track on the front side, where a wide path would obstruct the path of incident light. Meanwhile, the wider conductor can be made thinner than in the past (typically less than 50 μm) and still have low resistance. The thin conductor is more flexible and reduces stress. Seventh, the spacing between solar cells can be made small (for example, 1 mm or less) since no provision for stress relief of thick Cu interconnects needs to be maintained. This improves the module efficiency and reduces the module material cost (less glass, polymer, and backsheet due to reduced area).

FIGS. 4-7 depict electrical components in an assembly of solar cells, to illustrate an example circuit arrangement. FIG. 4 depicts the front side of an array 400 of solar cells with front and back metal contacts. Each solar cell 410 has first and second front metal contacts 420 and 430, respectively. The first and second front metal contacts 420 and 430 are configured as linear strips that extend horizontally across the front side of the solar cell 410. First and second back metal contacts are similarly arranged on the back side of the solar cell (not shown). Front metal contacts are of negative polarity, and back metal contacts are of positive polarity. The array 400 of solar cells includes a first row 440 and a second row 450 of solar cells. The linear metal contacts 420 and 430 of each solar cell 410 are positioned to be aligned with the metal contacts of adjacent solar cells in each row. In the completed assembly, solar cells 410 in the same row can be connected in series, such that negative contacts on a first solar cell are connected to positive contacts on a second solar cell adjacent to the first solar cell. Spacing is provided between adjacent solar cells to allow for thermal expansion. Adjacent solar cells 410 and 470 in the same row are separated by a gap 460, to provide an area where the front circuitry of the first solar cell may be electrically connected to the back circuitry on the second solar cell. The gap 460 may be less than 3 mm in width. In some embodiments, the gap 460 is about 1 mm or less.

FIG. 5 depicts a front sheet 500, which provides a front metal circuit plane. An array 505 is provided of pairs 510 of first and second front bus bars 520 and 530, arranged into a first row 540 and a second row 550. The bus bars are configured as linear strips, and each pair 510 is aligned linearly with the other pairs in each row. The bus bars are configured so that they may be positioned over respective metal contacts in the array 400 of solar cells 410 illustrated in FIG. 4. Accordingly, the first front bus bar 520 would be positioned to be electrically connected to the first front metal contact 420, for a matching solar cell 410. And the second front bus bar 530 would be positioned to be electrically connected to the second front metal contact 430.

Further, the first and second front bus bars 520 and 530 may be longer than the corresponding front metal contacts 420 and 430, such that when the front sheet 500 is positioned over the array 400 of solar cells, the front bus bars may extend horizontally over a horizontal edge of solar cell 410 into the gap 460 between adjacent solar cells. In this example, the front bus bars extend horizontally towards a distal edge disposed on the right hand side of each solar cell. (It is to be understood that this description may vary depending on one's viewing perspective.) This pattern can be repeated, as illustrated in the figures herein. In addition, adjacent pairs 510 of front bus bars 520 and 530 in the same row are separated by a gap 560 for electrical separation. In one embodiment, metal contacts for the front bus bars 520 and 530 are made on a PVF substrate or other plastic substrates. In a further embodiment, interconnect material (not shown) may be used to provide electrical connections, as discussed above. Layers of encapsulant material may also be provided, as discussed above.

FIG. 6 depicts a backsheet 600, which provides a back metal circuit plane. An array 605 is provided of pairs 610 of first and second back bus bars 620 and 630, arranged into a first row 640 and a second row 650. The bus bars are configured as linear strips, and each pair 610 is aligned linearly with the other pairs in each row. The bus bars are configured so that they may be positioned under respective metal contacts in the array 400 of solar cells 410 illustrated in FIG. 4. Accordingly, the first back bus bar 620 would be positioned to be electrically connected to the first back metal contact (not shown), for a matching solar cell 410. And the second back bus bar 630 would be positioned to be electrically connected to the second back metal contact (not shown).

Further, the first and second back bus bars may be longer than the matching back metal contacts, such that when the array 400 of solar cells is positioned over the backsheet 600, the back bus bars 680 and 690 extend horizontally past a horizontal edge of the second solar cell 470 into the gap 460 between the adjacent solar cells 410 and 470. In this example, the back bus bars extend horizontally over an edge that is on the opposite side of the solar cell from the edge over which the front bus bars extend. Thus, the back bus bars extend horizontally towards a proximate edge disposed on the left hand side of each solar cell. (It is to be understood that this description may vary depending on one's viewing perspective.) This pattern may be repeated, as illustrated in the figures herein. In addition, adjacent pairs (610 and 695) of back bus bars in the same row, may be separated by a gap 660 for electrical separation. In one embodiment, metal contacts for the back bus bars may be made on a PVF substrate or other plastic substrates. In a further embodiment, interconnect material (not shown) may be used to provide electrical connections, as discussed above. Layers of encapsulant material may also be provided, as discussed above.

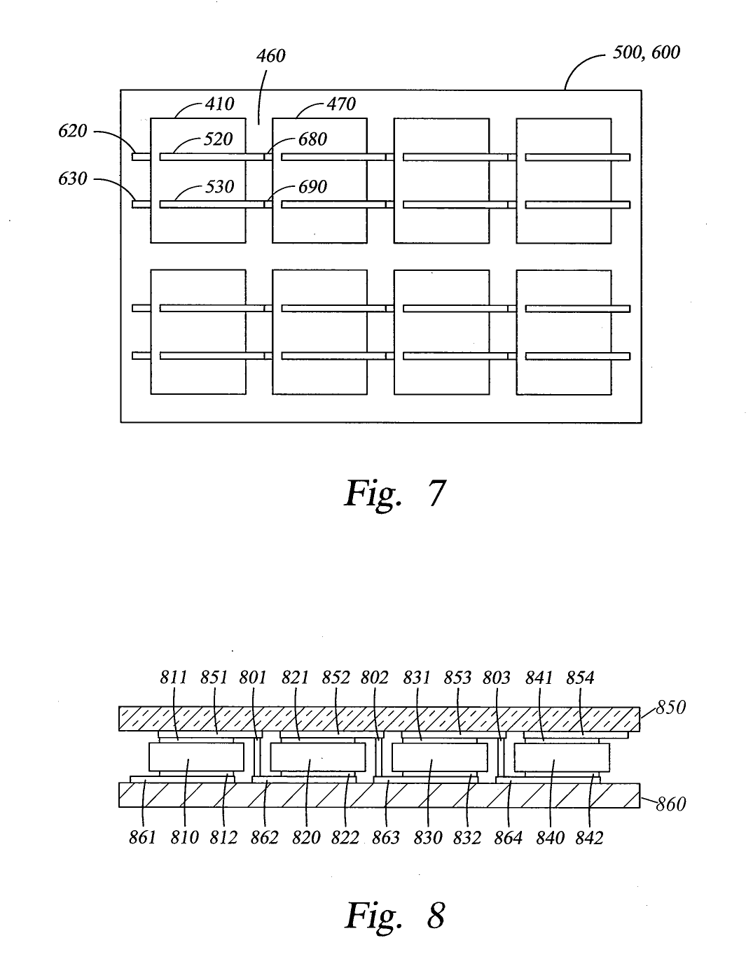

FIG. 7 provides a schematic diagram of an assembly of solar cells connected by the front and back metal circuit sheets, by combining the layers illustrated in FIG.'s 4-6. (Electrical connection may be made by a lamination step, as discussed above, in a monolithic assembly method.) Using solar cells 410 and 470 as an example, it can be seen that the front bus bars 520 and 530 may overlay and connect to the front electrical contacts 420 and 430, respectively, on the first solar cell 410. The front bus bars 520 and 530 do not extend over the distal (right) edge of the solar cell 410, and may be offset from the proximate edge by a distance. The front bus bars extend horizontally over the distal (right) edge of the first solar cell 410 so as to partially overlay the gap 460, but not so far as to overlay the next adjacent solar cell 470 in the row. The first and second back bus bars 620 and 630 underlay and connect to the back electrical contacts on the solar cell 410 (not shown), and extend horizontally past the proximate (left) edge of the solar cell 410 for further electrical connections. The second pair of back bus bars 680 and 690 underlay and connect to the back electrical contacts on the second solar cell 470 (not shown), and extend horizontally past the proximate edge of the second solar cell 470 and partially into the gap region 460 between the adjacent solar cells 410 and 470. The second pair of back bus bars 680 and 690 may then be positioned underneath the first pair of front bus bars 520 and 530. Overlapping bus bars may then be placed in electrical connection, so that negative contacts on the front side of solar cell 410 are connected in series to positive contacts on the back side of solar cell 470. In this way dual electrical contacts on adjacent solar cells in a row may be connected in series. This pattern may be repeated, as illustrated in the figures herein, to create a weave pattern. In some embodiments, interconnect material is provided between overlapping bus bars. Electrical connections may be made during a lamination step, wherein interconnect material may punch through surrounding encapsulant and bond to the bus bars.

FIG. 8 illustrates an expanded cross section view of a module assembly. A row of first, second, third and fourth back metal contacts 861, 862, 863 and 864 are provided on a backsheet 860. A row of first, second, third and fourth solar cells 810, 820, 830 and 840 is positioned over the backsheet 860. And a front sheet 850 is positioned over the row of solar cells. The front sheet 850 has a row of first, second, third and fourth front electrical contacts 851, 852, 853 and 854 are provided on a front sheet 850.

The first solar cell has a bottom electrical contact 812 and a top electrical contact 811. The bottom electrical contact 812 is placed in electrical connection with the first back metal contact 861, and the top electrical contact 811 is placed in electrical connection with the first front metal contact 851. The first back metal contact 861 is positioned so as to extend horizontally past a first or proximate end (shown as the left side) of the first solar cell 810, but not to extend the past a second or distal end (shown as the right side) of the first solar cell. The top electrical contact 811 is placed in electrical connection with the first front metal contact 851 on the front sheet 850. The first front metal contact 851 is positioned so as to extend horizontally past the second end of the first solar cell 810, but not to extend the past the first end of the first solar cell 810.

The configuration of electrical connections is repeated for the other solar cells. Accordingly, the second solar cell 820 has a bottom electrical contact 822 placed in electrical connection with the second back metal contact 862, and a top electrical contact 821 placed in electrical connection with the second front metal contact 852. The second back metal contact 862 extends horizontally past a first end of the second solar cell 820, but not a second end. And the second front metal contact 852 extends horizontally past the second end of the second solar cell 820, but not the first end. Similarly, the third solar cell 830 has a bottom electrical contact 832 placed in electrical connection with the third back metal contact 863, and a top electrical contact 831 placed in electrical connection with the third front metal contact 853. The third back metal contact 863 extends horizontally past a first end of the third solar cell 830, but not a second end. And the third front metal contact 853 extends horizontally past the second end of the second solar cell 830, but not the first end. In addition, the fourth solar cell 840 has a bottom electrical contact 842 placed in electrical connection with the fourth back metal contact 864, and a top electrical contact 841 placed in electrical connection with the fourth front metal contact 854. The fourth back metal contact 864 extends horizontally past a first end of the fourth solar cell 840, but not a second end. And the fourth front metal contact 854 extends horizontally past the second end of the fourth solar cell 840, but not the first end.

As shown in FIG. 8, the row of solar cells are electrically connected in series by connecting the front metal contact of one solar cell to the back metal contact of an adjacent solar cell in a gap between the two solar cells. Interconnect material may be used to make the electrical connection. Accordingly, the first front metal contact 851 is electrically connected by a first interconnection 801 to the second back metal contact 862. The second front metal contact 852 is electrically connected by a second interconnection 802 to the third back metal contact 863. And the third front metal contact 853 is electrically connected by a third interconnection 803 to the fourth back metal contact 864. The first back metal contact 861 may provide a positive terminal for further attachment in an electrical circuit. And the fourth front metal contact 854 may provide a negative terminal for further attachment in the electrical circuit. Additional interconnect material, not shown may be used to provide electrical connections. Electrical connections may also be established during a lamination step, as discussed in other embodiments above.

This pattern may be repeated to add more solar cells to the row of solar cells in the assembly. This pattern may also be repeated to add more rows of solar cells adjacent to the row illustrated in FIG. 8. Strings of series-connected solar cell may be electrically connected with metal ribbons or busses to complete the circuit. In the example shown in FIG. 7, each string of solar cells has two strings of electrical contacts. For example, the first pair of back bus bars in a row (e.g., first and second back bus bars 620 and 630) extend near to a first edge of the backsheet, for further electrical connection, and the last pair of front bus bars in the row extend near an edge of the front sheet that is opposite the first edge of the backsheet.

In some embodiments, the two strings of electrical contacts may be electrically connected in parallel by an end bus (not shown). Adjacent rows of solar cells may be connected by end busses so that two or more rows of solar cells are connected in series to form a complete circuit. In other embodiments, adjacent rows of solar cells may be connected in parallel, or in some combination of series and parallel circuits. The repeatability of the patterns and the modular assembly process allow for a variety of electrical circuit paths to be created.

The efficient production methods and assembly configurations provided herein also allow for further reducing gap space between solar cells. In one embodiment, gaps between adjacent solar cells in a row are about 1 mm or less. In another embodiment, gaps may be provided that are less than 3 mm long.

According to these and other embodiments, panels of solar cells may be assembled having various numbers of solar cells in various configurations. In one example, a monolithic assembly may be provided with 36 solar cell modules using 156×156-mm conventional crystalline silicon solar cells in a 4×9 array. In another example, a solar cell module assembly may be provided having 60 solar cells in a 6×10 array, having about 1.65 square meters of front surface area. Alternatively, a 10×6 array may be provided. In yet another example, an assembly of solar cells is provided having 72 cells. The 72 solar cells may be provided in an 8×9 array or a 9×8 array.

While the foregoing is directed to embodiments of the present invention, other and further embodiments of the invention may be devised without departing from the basic scope thereof, and the scope thereof is determined by the claims that follow.

1. An apparatus for generating photovoltaic power, comprising
an array of solar cells having front electrical contacts and back electrical contacts, wherein a first set of the solar cells in the array are positioned to be electrically connected in series;
a back circuit sheet comprising an array of back metal contacts, wherein a first set of the back metal contacts are positioned to electrically connect to corresponding back electrical contacts on the first set of solar cells; and
a front circuit sheet comprising an array of front metal contacts, wherein a first set of the front metal contacts are positioned to electrically connect to corresponding front electrical contacts on the first set of solar cells.

2. The apparatus of claim 1, wherein one or more of the back metal contacts in the back circuit sheet are positioned to electrically connect to one or more of the front metal contacts in the front circuit sheet in an area defined by one or more gaps between adjacent solar cells in the first set of solar cells.

3. The apparatus of claim 2, further comprising:
one or more back-side interconnect materials that establish a plurality of electrical connections between the back circuit sheet and the back electrical contacts in the array of solar cells; and
one or more front-side interconnect materials that establish a plurality of electrical connections between the front circuit sheet and the front electrical contacts in the array of solar cells.

4. The apparatus of claim 3, wherein there is less interconnect material on the front-side than on the back-side.

5. The apparatus of claim 3, wherein the front metal contacts are thinner than the back metal contacts.

6. The apparatus of claim 5, wherein the front metal contacts comprise thin lines of copper, and the back metal contacts comprise aluminum and copper.

7. The apparatus of claim 3, wherein the front metal contacts comprise front metal bus bars, and the back metal contacts comprise back metal bus bars, the front metal bus bars on the first set of solar cells extend horizontally past a proximate edge of each of the solar cells, and the back metal bus bars on the first set of solar cells extend horizontally past a distal edge of each of the solar cells.

8. The apparatus of claim 7, wherein an interconnect material electrically connects the front metal bus bars to the back metal bus bars so as to connect the first set of solar cells in series.

9. The apparatus of claim 8, further comprising:
a transparent polymer layer positioned over the front circuit sheet; and
a transparent front layer positioned over the transparent polymer layer.

10. The apparatus of claim 3, further comprising one or more layers of an encapsulant polymer, wherein the electrical connections are formed during a lamination step.

11. A module assembly of solar cells comprising:
a backsheet;
a back circuit positioned over the back sheet and having a set of back metal contacts;
an array of solar cells positioned over the back metal circuit plane, wherein each of the solar cells has front electrical contacts of negative polarity and back electrical contacts of positive polarity; and
a front circuit positioned over the array of solar cells and having a set of front metal contacts,
wherein at least a first set of the solar cells are positioned to be electrically connected in series by the back and front circuits.

12. The module assembly of claim 11, wherein, for the first set of solar cells, each back electrical contact of a solar cell is electrically connected to a corresponding back metal contact on the back circuit, and each front electrical contact of a solar cell is electrically connected to a corresponding front metal contact on the front circuit, and
wherein at least one front metal contact, connected to a first solar cell, is electrically connected to at least one back metal contact connected to a second solar cell positioned adjacent to the first solar cell.

13. The module assembly of claim 12, further comprising:
a first pattern of one or more interconnect materials providing electrical connections between the back circuit and the back electrical contacts of the array of solar cells; and
a second pattern of one or more interconnect materials providing electrical connections between the front circuit and the front electrical contacts of the array of solar cells.

14. The module assembly of claim 13, wherein the first pattern of one or more interconnect materials further provides electrical connections between the front circuit and the back circuit, and the electrical connections between the front circuit and the back circuit are formed in at least a plurality of gaps between adjacent solar cells in the first set of solar cells that are connected in series.

15. A method for monolithic manufacturing assembly of a solar cell panel, comprising the steps of:
obtaining a set of solar cells having similar electrical properties that may be used together to manufacture a solar cell panel;
laying down a backsheet;
providing a back metal circuit sheet over the backsheet;
positioning an array of solar cells over a pattern of interconnect material, wherein each solar cell has one or more front electrical contacts and one or more back electrical contacts;
providing a front metal circuit sheet over the interconnect material; and
laying down a front cover over the front metal circuit sheet.

16. The method of claim 15, further comprising:
providing a back pattern of interconnect material over the back metal circuit sheet;
providing a back encapsulant over the interconnect material and the back metal circuit sheet, before positioning the array of solar cells;
providing a front encapsulant over the array of solar cells; and
providing a front pattern of interconnect material over the front encapsulant, before providing the front metal circuit sheet.

17. The method of claim 16, further comprising:
providing a back polymer layer over the backsheet before providing the back metal circuit sheet; and
providing a front polymer layer over the front metal circuit sheet before laying down the front cover.

18. The method of claim 16, further comprising providing electrical connections during a lamination step.

19. The method of claim 16, wherein less interconnect material is used on the back pattern than on the front pattern, and the front metal circuit sheet comprises thinner metal contacts than the back metal circuit sheet.

20. The method of claim 15, wherein the back metal circuit sheet further comprises back metal bus bars and a pattern of interconnect material over portions of the back metal bus bars, positioned to make electrical connection to the back electrical contacts of the solar cells and the front circuit sheet.
